(19) United States
(12) Patent Application Publication
(10) Pub. No.: US 2025/0266648 A1
(43) Pub. Date: Aug. 21, 2025

(54) Shield Contact System

(71) Applicant: TE Connectivity Solutions GmbH, Schaffhausen (CH)

(72) Inventor: Ba Pham, Winston Salem, NC (US)

(73) Assignee: TE Connectivity Solutions GmbH, Schaffhausen (CH)

(21) Appl. No.: 18/583,415

(22) Filed: Feb. 21, 2024

(51) Int. Cl. H01R 13/6582; H01R 43/26

(52) U.S. Cl. CPC H01R 13/6582; H01R 43/26

(57) ABSTRACT

A shield contact system includes a first shield having a first shield body and a protrusion extending from the first shield body, and a second shield having a second shield body and a contact beam extending from the second shield body. The first shield and the second shield are inserted together along an insertion direction from a deflected state to a mated state. The protrusion deflects the contact beam away from the first shield body in the deflected state. The contact beam abuts the first shield body in the mated state.

### FIELD OF THE INVENTION

The present invention relates to a contact system and, more particularly, to a contact system connecting a first shield to a second shield.

### BACKGROUND

In a shield contact system, a male shield is inserted into a female shield to form a connection between the shields. The female shield has a contact beam that extends into the space in which the male shield is received. The contact beam contacts an outer surface of the male shield to form the connection and slides along the outer surface of the male shield during insertion of the male shield.

During insertion of the male shield, it is common for the leading edge of the male shield to contact a contact point of the contact beam of the female shield, shaving off or otherwise damaging the contact point. The contact point of the contact beam also slides along the outer surface of the male shield over a significant portion of the insertion of the male shield, leading to a long wiping distance that increases wear on the contact point. The contact points of current contact systems can thus suffer significant wear during each mating cycle of the male shield and the female shield, which leads to a limited number of mating cycles in the usable life of the shield contact system.

### SUMMARY

A shield contact system includes a first shield having a first shield body and a protrusion extending from the first shield body, and a second shield having a second shield body and a contact beam extending from the second shield body. The first shield and the second shield are inserted together along an insertion direction from a deflected state to a mated state. The protrusion deflects the contact beam away from the first shield body in the deflected state. The contact beam abuts the first shield body in the mated state.

### BRIEF DESCRIPTION OF THE DRAWINGS

The invention will now be described by way of example with reference to the accompanying Figures, of which:

FIG. 1 is a perspective view of a shield contact system according to an embodiment;

FIG. 2 is a perspective view of a first shield of the shield contact system;

FIG. 3 is a perspective view of a second shield of the shield contact system;

FIG. 4 is a sectional perspective view of the first shield and the second shield in an inserted state of the shield contact system;

FIG. 5 is a sectional perspective view of the first shield and the second shield in a deflected state of the shield contact system;

FIG. 6 is a detail sectional end view of a portion of the first shield and the second shield in the deflected state, taken along line 6-6 in FIG. 5; and

FIG. 7 is a sectional perspective view of the first shield and the second shield in a mated state of the shield contact system taken along line 7-7 in FIG. 1.

### DETAILED DESCRIPTION OF THE EMBODIMENTS

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art. In addition, in the following detailed description, for purposes of explanation, numerous specific details are set forth to provide a thorough understanding of the disclosed embodiments. However, it is apparent that one or more embodiments may also be implemented without these specific details.

Throughout the drawings, only one of a plurality of identical elements may be labeled in a figure for clarity of the drawings, but the detailed description of the element herein applies equally to each of the identically appearing elements in the figure. Throughout the specification, directional descriptors are used such as “circumferential direction,” “insertion direction,” and “radial direction”. These descriptors are merely for clarity of the description and for differentiation of the various directions. These directional descriptors do not imply or require any particular orientation of the disclosed elements.

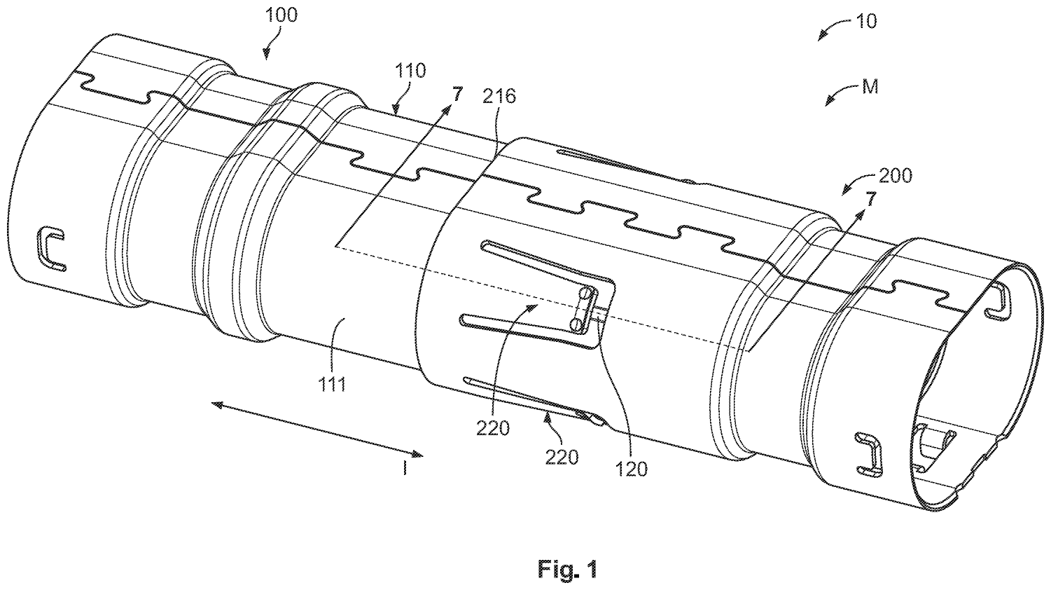

A shield contact system 10 according to an embodiment is shown in a mated state M in FIG. 1. The shield contact system 10 includes a first shield 100 and a second shield 200 that is matable with the first shield 100 along an insertion direction I.

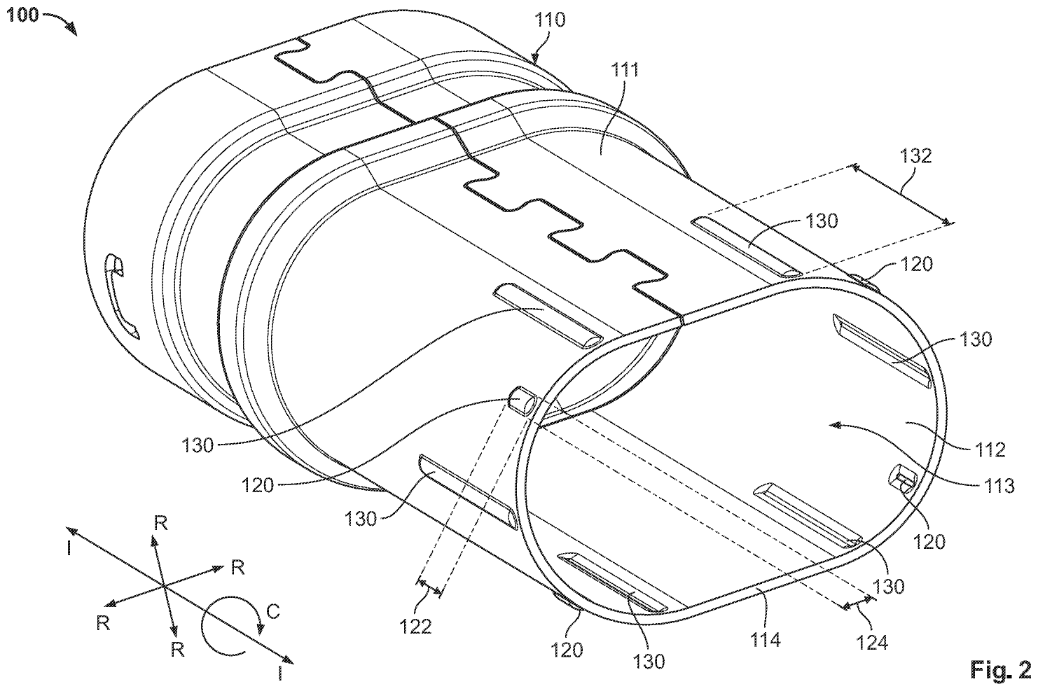

The first shield 100, as shown in FIG. 2, has a first shield body 110, a plurality of protrusions 120 extending from the first shield body 110, and a plurality of ribs 130 extending from the first shield body 110.

As shown in FIG. 2, the first shield body 110 has a first exterior surface 111 and a first interior surface 112 opposite the first exterior surface 111 in a radial direction R perpendicular to the insertion direction I. The first shield body 110 defines a first receiving space 113 extending along the insertion direction I and has a first leading edge 114 at one end in the insertion direction I. The first shield body 110 defines the first receiving space 113 with a rounded-rectangular cross-sectional shape in the shown embodiment. In other embodiments, the first shield body 110 could define the first receiving space 113 as a circular cross-sectional shape, or any other cross-sectional shape used in shield contacts.

The protrusions 120 each extend from the first exterior surface 111 of the first shield body 110 in the radial direction R, as shown in FIG. 2. The protrusions 120 each have a protrusion length 122 along the insertion direction I and a protrusion width 124 in a circumferential direction C of the first shield 100 around the insertion direction I. The protrusions 120 are each positioned adjacent to the first leading edge 114 but spaced apart from the first leading edge 114 along the insertion direction I.

The protrusions 120 are distributed in the circumferential direction C around the first shield body 110. In the shown embodiment, four protrusions 120 are distributed around the first shield body 110. This embodiment is merely exemplary and, in other embodiments, less than four or more than four protrusions 120 may be distributed around the first shield body 110 and may be arranged differently than in the positions shown in FIG. 2.

The ribs 130 each extend from the first exterior surface 111 of the first shield body 110 in the radial direction R, as shown in FIG. 2. The ribs 130 each have a rib length 132 along the insertion direction I. The rib length 132 is longer than the protrusion length 122 in the shown embodiment. The ribs 130 are each positioned adjacent to the first leading edge 114 but spaced apart from the first leading edge 114 along the insertion direction I. In the shown embodiment, the ribs 130 are each spaced the same distance from the first leading edge 114 along the insertion direction I as the protrusions 120.

The ribs 130 are distributed in the circumferential direction C around the first shield body 110. In the shown embodiment, six ribs 130 are distributed around the first shield body 110. This embodiment is merely exemplary and, in other embodiments, less than six or more than six ribs 130 may be distributed around the first shield body 110 and may be arranged differently than in the positions shown in FIG. 2.

The first shield 100 is formed of a conductive material, such as aluminum. In the shown embodiment, the first shield 100 is monolithically formed in a single piece from the conductive material with the first shield body 110, the protrusions 120, and the ribs 130; in this embodiment, the protrusions 120 and the ribs 130 may be embossed on the first shield body 110 and the first shield body 110 is formed in a sheet and bent into the shape shown in FIG. 2. In other embodiments, the first shield body 110 may be formed separately and attached together with the protrusions 120 and the ribs 130.

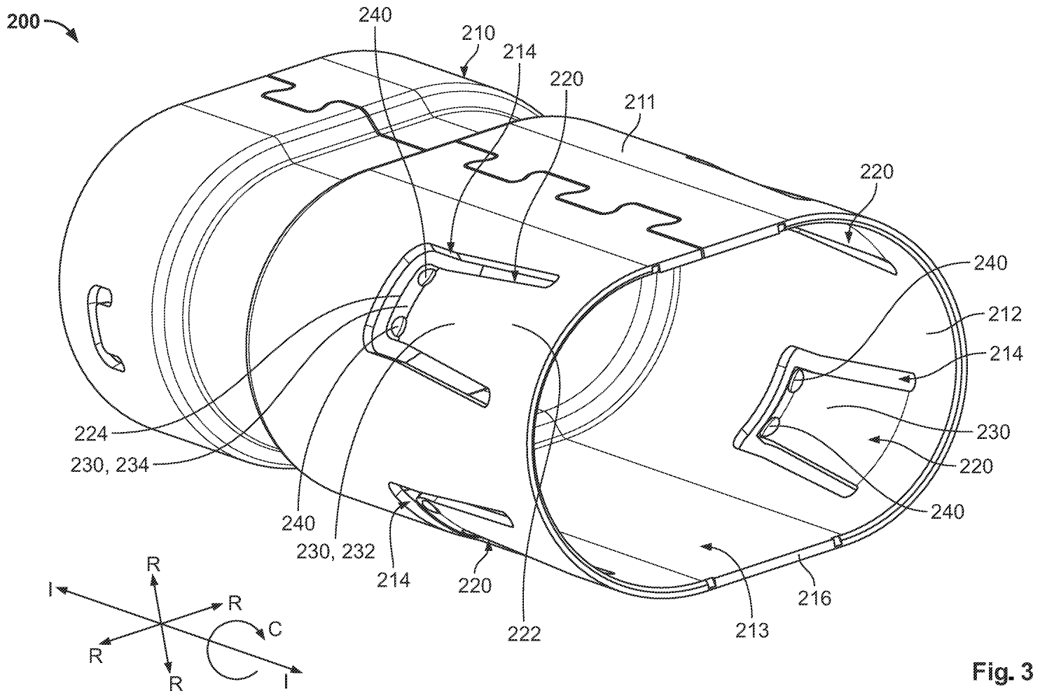

The second shield 200, as shown in FIG. 3, has a second shield body 210 and a plurality of contact beams 220 extending from the second shield body 210.

As shown in FIG. 3, the second shield body 210 has a second exterior surface 211 and a second interior surface 212 opposite the second exterior surface 211 in the radial direction R. The second shield body 210 defines a second receiving space 213 extending along the insertion direction I and has a plurality of beam openings 214 extending through the second shield body 210 in the radial direction R and communicating with the second receiving space 213. The second shield body 210 has a second leading edge 216 at one end in the insertion direction I. The second shield body 210 defines the second receiving space 213 with a shape corresponding to the shape of the first receiving space 113 of the first shield body 110. In the shown embodiment, the second shield body 210 defines the second receiving space 213 with a rounded-rectangular cross-sectional shape in the shown embodiment. In other embodiments, the second shield body 210 could define the second receiving space 213 as a circular cross-sectional shape, or any other cross-sectional shape corresponding to the first receiving space 113 and used in shield contacts.

The contact beams 220 are each positioned in one of the beam openings 214, as shown in FIG. 3. The contact beams 220, in the shown embodiment, are each cantilevered from the second shield body 210 and extend from a fixed end 222 to a cantilevered end 224 along the insertion direction I. In the shown embodiment, the cantilevered end 224 is positioned further from the second leading edge 216 of the second shield body 210 than the fixed end 222 along the insertion direction I. In another embodiment, the contact beam 220 may extend in the reverse direction with the cantilevered end 224 positioned closed to the second leading edge 216 than the fixed end 222 along the insertion direction I. In other embodiments, the contact beams 220 may be connected at both ends but otherwise function as described herein.

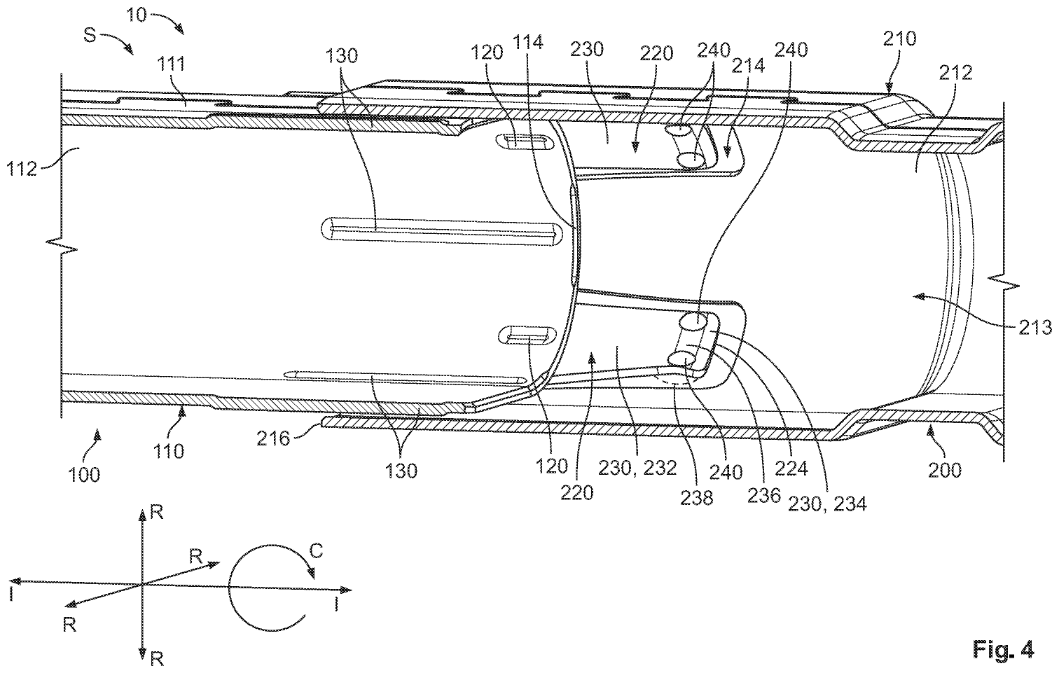

Each of the contact beams 220, as shown in FIGS. 3 and 4, has a beam body 230 and a pair of contact points 240. The beam body 230 has a first beam section 232 and a second beam section 234 connected to the first beam section 232 at an intersection 236, shown in detail in FIG. 4. The second beam section 234 is bent at an angle 238 with respect to the first beam section 232. The angle 238 is greater than 90° and less than 180°.

The contact points 240 are positioned at the intersection 236 of the first beam section 232 and the second beam section 234 and protrude, as shown in FIG. 4, from the beam body 230 in the radial direction R toward the second receiving space 213. The contact points 240 are spaced apart from the cantilevered end 224 along the insertion direction I. The contact points 240 on each contact beam 220 include a pair of contact points 240 that have a same position along the insertion direction I and are spaced apart from one another in the circumferential direction C of the second shield 200.

The contact beams 220, as shown in FIG. 3, are distributed in the circumferential direction C around the second shield body 210. In the shown embodiment, four contact beams 220 are distributed around the second shield body 210. This embodiment is merely exemplary; the number of contact beams 220 of the second shield 200 and the location of the contact beams 220 on the second shield 220 in the circumferential direction C corresponds to the number of protrusions 120 of the first shield 100 and the locations of the protrusions 120 on the first shield 100 in the circumferential direction C.

The second shield 200 is formed of a conductive material, such as aluminum. In the shown embodiment, the second shield 200 is monolithically formed in a single piece from the conductive material with the second shield body 210 and the contact beams 220. The second shield body 210 may be formed in a sheet, with the contact beams 220 punched and embossed, and then bent into the shape shown in FIG. 3. In other embodiments, the second shield body 210 may be formed separately and attached together with the contact beams 220.

The mating of the first shield 100 and the second shield 200 to form the connection of the shield contact system 10 will now be described in greater detail primarily with respect to FIGS. 4-7.

The first shield 100 and the second shield 200 are inserted together along the insertion direction I. As shown in FIG. 4, the first leading edge 114 of the first shield body 110 is positioned within the second leading edge 216 of the second shield body 210 and the first shield 100 is inserted into the second receiving space 213. The first shield 100 is inserted into the second shield 200 in an intermediate position, referred to herein as an inserted state S, which is between a separated state of the shields 100, 200 and the mated state M of the shields 100, 200.

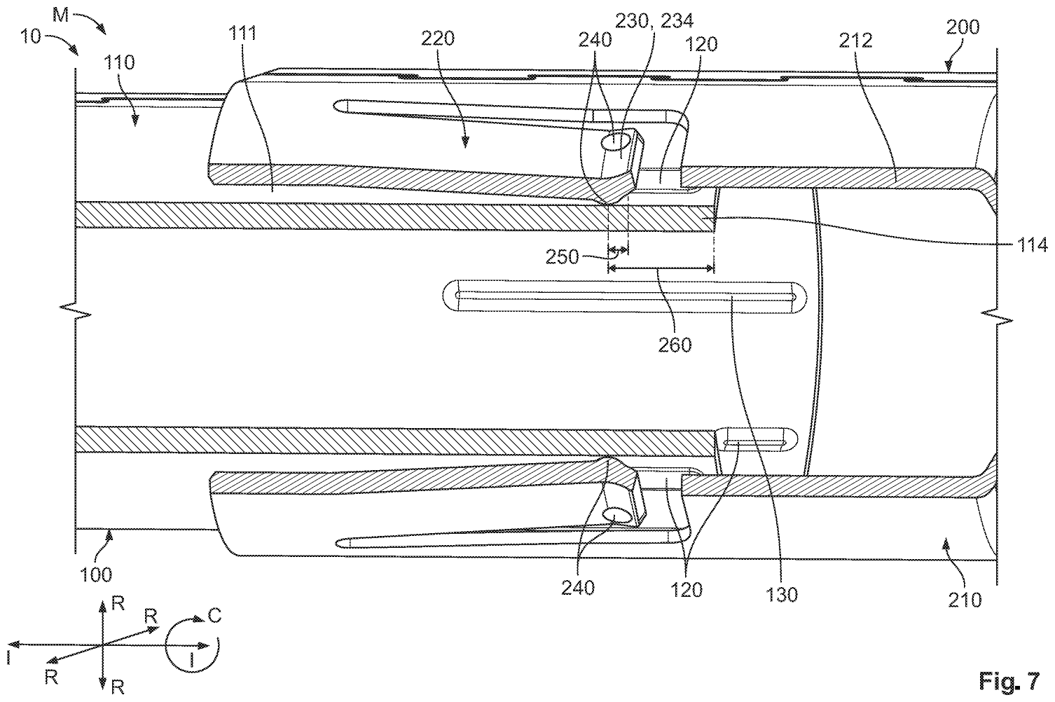

In the inserted state S shown in FIG. 4, the ribs 130 abut the second interior surface 212 of the second shield body 210. Due to their position spaced apart from the first leading edge 114, the ribs 130 allow for a greater tolerance in inserting the first leading edge 114 within the second leading edge 216 and, as the first shield 100 is further inserted along the insertion direction I, engage the second interior surface 212 to center and more precisely position the first shield 100 in the second receiving space 213. The ribs 130 remain in abutment with the second interior surface 212 to provide this centering during insertion along the insertion direction I to the mated state M shown in FIGS. 1 and 7.

Each of the protrusions 120 is aligned with one of the contact beams 220 during insertion of the first shield 100 along the insertion direction I. In the inserted state S shown in FIG. 4, the protrusions 120 initially contact the contact beams 220 at the fixed ends 222 but have not yet deflected the contact beams 220.

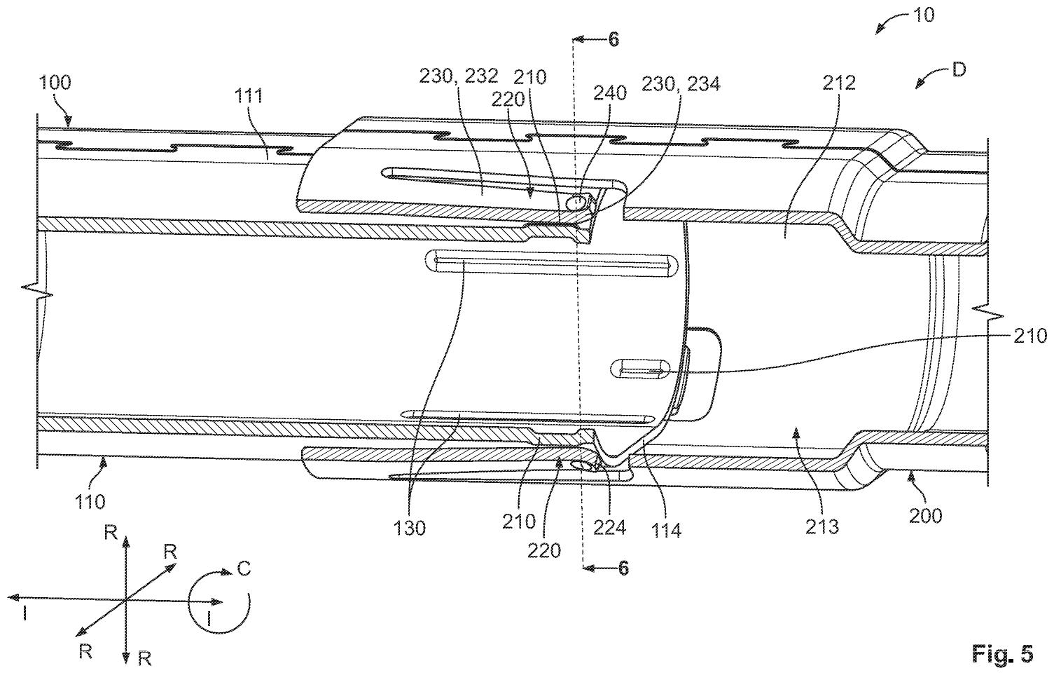

The first shield 100 is moved further along the insertion direction I in the second shield 200 to a deflected state D shown in FIG. 5. As each of the protrusions 120 moves along one of the contact beams 220 in the insertion direction I, the protrusion 120 deflects the contact beam 220 away from the first shield body 110 and away from the second receiving space 213 in the radial direction R. The protrusion 120 deflects the contact beam 220 away from the first shield body 110 such that the contact points 240 of the contact beam 220 do not contact the first shield body 110 prior to the deflected state D or in the deflected state D. Due to the deflection of the beams 220 imparted by movement of the protrusions 120, the first leading edge 114 of the first shield body 110 also does not contact the contact points 240 on the contact beams 220. The ribs 130 remain in abutment with the second interior surface 212 of the second shield body 210 in the deflected state D.

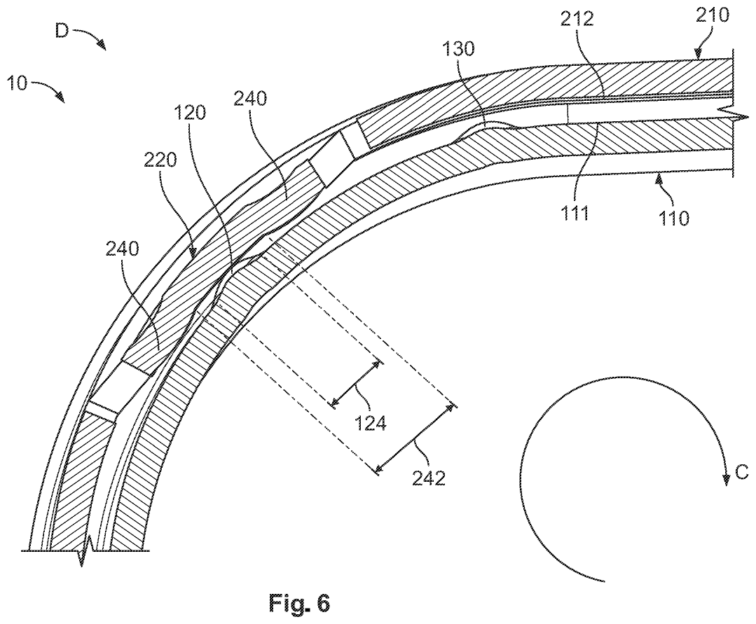

FIG. 6 shows in greater detail that, when the protrusion 120 deflects the contact beam 220 in the deflected state D, the contact points 240 are deflected away from the first shield body 110 and do not contact the first exterior surface 111 of the first shield body 110. As the first shield 100 is inserted further into the second receiving space 213 of the second shield 200 along the insertion direction I from the deflected state D to the mated state M, the protrusion 120 passes between the contact points 240. As shown in FIG. 6, a distance 242 between the contact points 240 in the circumferential direction C is greater than the protrusion width 124, allowing the protrusion 120 to pass through while the contact beam 220 is deflected without abutting the contact points 240.

The first shield 100 is further inserted together with the second shield 200 along the insertion direction I from the deflected state D shown in FIG. 5 to the mated state M shown in FIGS. 1 and 7. When an end of the protrusion 120 further from the first leading edge 114 reaches the second beam section 234 of the contact beam 220, the contact beam 220 elastically returns from the deflected position and the contact points 240 abut the first exterior surface 111 of the first shield body 110. The contact beam 220 thus abuts the first shield body 110 in the mated state M, as shown in FIG. 7. The first shield 100 may be further inserted a short distance along the insertion direction I with the contact points 240 sliding along the first exterior surface 111 by a correspondingly short wiping distance 250. The wiping distance 250 is less than a distance 260 between the contact points 240 and the first leading edge 114 along the insertion direction I. The ribs 130 remain in abutment with the second interior surface 212 of the second shield body 210 in the mated state D.

The shield contact system 10 described above and shown in the drawings is one possible embodiment that incorporates the features of the invention. In another embodiment, for example, the second shield 200 can be received within the first shield 100. In this embodiment, the protrusion 120 is positioned on the first interior surface 112 and extends into the first receiving space 113; this embodiment has the same function as described above, but the contact beams 220 deflect away from and then contact the first interior surface 112 of the first shield 100 in the mated state M.

In the mated state M, the first shield 100 and the second shield 200 are electrically connected. The shield contact system 10 may be part of an electrical connector system that electrically connects electrical components. In this application, the first shield 100 is positioned around a first dielectric having a first contact and the second shield 200 is positioned around a second dielectric having a second contact. The first shield 100 and the second shield 200 move into the mated state M described above to provide electromagnetic shielding for the mating between the first contact and the second contact.

In the shield contact system 10 according to the embodiments described above, the protrusion 120 deflects the contact beam 220 away from the first shield body 110 during insertion, which prevents the first leading edge 114 from contacting or shearing the contact points 240 of the contact beam 220. The contact beam 220 remains deflected during insertion, and the contact points 240 remain separated from the first shield body 110, until an end of the protrusion 120 further from the first leading edge 114 reaches the second beam section 234. Thus, the contact points 240 of the contact beam 220 only have a short wiping distance 250 along the first exterior surface 111 of the first shield body 110 to the mated state M. Further, the use of multiple contact points 240 on each contact beam 220 create a redundancy in the contact in case one of the points 240 wears faster due to variations of the first shield 100 and second shield 200 within the manufacturing tolerance. The shield contact system 10 of the present invention limits damage to the contact points 240 and decreases the wiping distance 250, minimizing wear and allowing the shield contact system 10 to be used over a greater number of mating cycles.

What is claimed is:

1. A shield contact system, comprising:
a first shield having a first shield body and a protrusion extending from the first shield body; and
a second shield having a second shield body and a contact beam extending from the second shield body, the first shield and the second shield are inserted together along an insertion direction from a deflected state to a mated state, the protrusion deflects the contact beam away from the first shield body in the deflected state, the contact beam abuts the first shield body in the mated state.

2. The shield contact system of claim 1, wherein the protrusion extends from a first exterior surface of the first shield body and the contact beam abuts the first exterior surface in the mated state.

3. The shield contact system of claim 2, wherein the first shield body is inserted into a second receiving space defined by the second shield body.

4. The shield contact system of claim 1, wherein the contact beam has a beam body and a contact point protruding from the beam body, the contact point abuts the first shield body in the mated state.

5. The shield contact system of claim 4, wherein the contact point is one of a pair of contact points of the contact beam, the contact points have a same position along the insertion direction and are spaced apart from one another in a circumferential direction of the second shield.

6. The shield contact system of claim 5, wherein the protrusion passes between the contact points along the insertion direction from the deflected state to the mated state.

7. The shield contact system of claim 4, wherein the contact point is not in contact with the first shield body in the deflected state.

8. The shield contact system of claim 4, wherein the contact beam is cantilevered from the second shield body and extends from a fixed end to a cantilevered end.

9. The shield contact system of claim 8, wherein the cantilevered end is positioned further from a second leading edge of the second shield body than the fixed end along the insertion direction.

10. The shield contact system of claim 8, wherein the beam body has a first beam section and a second beam section bent at an angle with respect to the first beam section.

11. The shield contact system of claim 10, wherein the contact point is positioned at an intersection of the first beam section and the second beam section, the contact point is spaced apart from the cantilevered end along the insertion direction.

12. The shield contact system of claim 1, wherein the protrusion is one of a plurality of protrusions of the first shield and the contact beam is one of a plurality of contact beams of the second shield, each of the protrusions is aligned with one of the contact beams during insertion along the insertion direction.

13. The shield contact system of claim 12, wherein the protrusions are distributed in a circumferential direction around the first shield body and the contact beams are distributed in the circumferential direction around the second shield body.

14. The shield contact system of claim 1, wherein the first shield has a rib extending from the first shield body, the rib abuts the second shield body in the deflected state and in the mated state.

15. The shield contact system of claim 14, wherein the rib has a rib length that is longer than a protrusion length of the protrusion along the insertion direction.

16. A process of connecting a shield contact system, comprising:
providing a first shield having a first shield body and a protrusion extending from the first shield body;
providing a second shield having a second shield body and a contact beam extending from the second shield body; and
inserting the first shield and the second shield together along an insertion direction to a mated state, the contact beam abuts the first shield body in the mated state, the protrusion deflects the contact beam away from the first shield body during insertion in a deflected state prior to reaching the mated state.

17. The process of claim 16, wherein the contact beam has a beam body and a contact point protruding from the beam body, the contact point abuts the first shield body in the mated state.

18. The process of claim 17, wherein the protrusion deflects the contact beam away from the first shield body during insertion before a first leading edge of the first shield body contacts the contact point.

19. The process of claim 18, wherein, during insertion, the contact point slides along the first shield body by a wiping distance to the mated state that is less than a distance between the contact point and a first leading edge of first shield body in the mated state.

20. The process of claim 17, wherein the contact point is one of a pair of contact points of the contact beam, the protrusion passes between the contact points during insertion.
